(19) United States
(12) Patent Application Publication
(10) Pub. No.: US 2024/0267125 A1
(43) Pub. Date: Aug. 8, 2024

(54) OPTICAL TRANSMISSION MODULE

(71) Applicant: SUMITOMO ELECTRIC INDUSTRIES, LTD., Osaka (JP)

(72) Inventors: Naoki ITABASHI, Osaka (JP); Tomoya SAEKI, Osaka (JP)

(21) Appl. No.: 18/430,960

(22) Filed: Feb. 2, 2024

(30) Foreign Application Priority Data
Feb. 8, 2023 (JP) 2023-017727

(51) Int. Cl. H04B 10/50; H04B 1/036

(52) U.S. Cl. CPC H04B 10/501; H04B 1/036

(57) ABSTRACT

An optical transmission module according to one embodiment includes: a metal stem having a signal terminal extending in a first direction and a support portion extending in the first direction; a dielectric block containing a dielectric material and having a semiconductor mounting surface and a heat conduction surface; an optical semiconductor element mounted on the semiconductor mounting surface; a temperature control element disposed between the metal stem and the heat conduction surface; a relay board for electrically connecting the signal terminal to the optical semiconductor element; and a heat insulation spacer having an insulation property and connected between the support portion and the relay board. Thermal conductivity of the heat insulation spacer is lower than the thermal conductivity of the support portion and lower than the thermal conductivity of the relay board.

### CROSS-REFERENCE TO RELATED APPLICATION

This application claims priority from Japanese Patent Application No. 2023-017727, filed on Feb. 8, 2023, the entire subject matter of which is incorporated herein by reference.

### TECHNICAL FIELD

The present disclosure relates to an optical transmission module.

### BACKGROUND

Japanese Unexamined Patent Publication No. 2011-108939 describes a TO-CAN type TOSA module. The TO-CAN type TOSA module includes a dielectric material for hermetic sealing, a stem having a plurality of wiring terminals for flowing high-frequency electrical signals and DC current, and an optical semiconductor light source element mounted on the stem. The stem has an upper layer of the stem made of a steel plate cold (SPC) with high thermal conductivity, a lower layer of the stem made of an iron-nickel-cobalt (Fe—Ni—Co) alloy with a small thermal expansion coefficient, and a nose protruding from the upper layer of the stem. The nose is integrally formed during press working of the stem. The nose is made of the metal material of SPC or the like the same as the upper layer of the stem. A relay line board is fixed to the nose with solder.

A Peltier element as a cooling element is mounted on the stem. A carrier for mounting various components is placed on the Peltier element. The lens for collimating light from the optical semiconductor light source element and a subcarrier substrate are mounted on the carrier. Chips monolithically integrated with laser diodes and optical modulator units are mounted on the subcarrier substrate as the optical semiconductor light source element. The carrier is connected to the nose via a plurality of bonding wires. The plurality of bonding wires extending from the carrier are configured to be connected to the nose and not directly connected to the stem.

Japanese Unexamined Patent Publication No. 2020-098837 discloses an optical subassembly. The optical subassembly includes an eyelet and an optical receptacle. The eyelet has a first surface and a second surface disposed opposite the first surface. The eyelet has a first penetrating hole that penetrates from the first surface to the second surface. A first lead terminal transmitting the electrical signal is inserted into a first penetrating hole. The dielectric material is filled between the first penetrating hole and the first lead terminal. The optical subassembly includes a conductive pedestal protruding from the first surface of the eyelet in the direction of extension of the first penetrating hole. The eyelet and the pedestal are integrally formed, and the eyelet and the pedestal constitute the stem.

The pedestal includes a third surface on which the relay board is placed. The optical subassembly includes an optical element performing photoelectric conversion between the optical signal and the electrical signal, and the relay board includes a conductor pattern connecting the electrical signal to the optical element. The spacer is interposed between the relay board and the third surface of the pedestal. The spacer provides electrical continuity between the back surface of the relay board and the pedestal. By providing this spacer, the thickness of the relay board can be reduced to as thin as 0.2 mm. As a result, the enlargement of the relay board is suppressed. The spacer is configured as a ceramic substrate such as aluminum nitride. Further, the configuration is disclosed in which the plurality of embedded via holes are provided in the ceramic substrate, and the front and back surfaces of the spacer are electrically connected.

### SUMMARY

The optical transmission module according to the present disclosure includes: a metal stem having a signal terminal extending in a first direction and a support portion extending in the first direction; a dielectric block containing a dielectric material and having a semiconductor mounting surface and a heat conduction surface; an optical semiconductor element mounted on the semiconductor mounting surface; a temperature control element disposed between the metal stem and the heat conduction surface; a relay board for electrically connecting the signal terminal to the optical semiconductor element; and a heat insulation spacer having an insulation property and connected between the support portion and the relay board. The thermal conductivity of the heat insulation spacer is lower than the thermal conductivity of the support portion and lower than the thermal conductivity of the relay board.

### BRIEF DESCRIPTION OF THE DRAWINGS

FIG. 1 is a perspective view of an optical transmission module according to an embodiment.

FIG. 2 is a side view of the optical transmission module according to the embodiment.

FIG. 3 is a plan view of the optical transmission module according to the embodiment.

FIG. 4 is a side view schematically illustrating a support portion, a relay board, and a heat insulation spacer of the optical transmission module according to the embodiment.

FIG. 5 is a plan view schematically illustrating the relay board and the heat insulation spacer of FIG. 4.

FIG. 6 is a plan view schematically illustrating a relay board and a heat insulation spacer according to Modified Example 1.

FIG. 7 is a side view schematically illustrating a support portion, a relay board, and a heat insulation spacer of an optical transmission module according to Modified Example 2.

FIG. 8 is a plan view schematically illustrating the relay board and the heat insulation spacer of the optical transmission module according to Modified Example 2.

FIG. 9 is a plan view schematically illustrating a relay board and a heat insulation spacer of an optical transmission module according to Modified Example 3.

FIG. 10 is a perspective view illustrating a heat insulation spacer according to Modified Example 4.

FIG. 11 is a perspective view illustrating a heat insulation spacer according to Modified Example 5.

FIG. 12 is a perspective view illustrating a heat insulation spacer according to Modified Example 6.

### DETAILED DESCRIPTION

In a TO-CAN type TOSA module described above, a stem has a metal nose protruding from an upper layer of the stem made of SPC. The relay line board is fixed to the nose with solder. The Peltier element adjusts the temperature of the optical element mounted on the carrier. The carrier is connected to the nose via the plurality of bonding wires. Therefore, heat from the stem flows into the carrier via the nose and the plurality of bonding wires. When heat from the stem flows into the carrier, there is a possibility that the temperature of the optical element cannot be efficiently controlled by the temperature control element such as the Peltier element.

An object of the present disclosure is to provide an optical transmission module that can efficiently control temperature of an optical element by a temperature control element.

According to the present disclosure, temperature of an optical element can be efficiently controlled by a temperature control element.

### DESCRIPTION OF EMBODIMENTS OF PRESENT DISCLOSURE

First, embodiments of an optical transmission module according to the present disclosure will be listed and described. The optical transmission module according to one embodiment includes (1): a metal stem having a signal terminal extending in a first direction and a support portion extending in the first direction; a dielectric block containing a dielectric material and having a semiconductor mounting surface and a heat conduction surface; an optical semiconductor element mounted on the semiconductor mounting surface; a temperature control element disposed between the metal stem and the heat conduction surface; a relay board for electrically connecting the signal terminal to the optical semiconductor element; and a heat insulation spacer having an insulation property and connected between the support portion and the relay board. A thermal conductivity of the heat insulation spacer is lower than the thermal conductivity of the support portion and lower than the thermal conductivity of the relay board.

This optical transmission module includes the metal stem having the signal terminal and the support portion, and the dielectric block. The dielectric block has the semiconductor mounting surface and the heat conduction surface. The temperature control element is disposed between the metal stem and the heat conduction surface of the dielectric block, and the optical semiconductor element is mounted on the semiconductor mounting surface of the dielectric block. This optical transmission module includes the relay board electrically connected to the optical semiconductor element, and the heat insulation spacer disposed between the relay board and the support portion. The thermal conductivity of the heat insulation spacer is lower than the thermal conductivity of the support portion and lower than the thermal conductivity of the relay board. Therefore, since heat from the support portion of the metal stem is insulated by the heat insulation spacer, the inflow of heat to the relay board can be suppressed. Therefore, by suppressing the inflow of heat from the support portion of the metal stem to the relay board, the temperature of the optical element can be efficiently controlled by the temperature control element.

(2) in (1) above, the thermal conductivity of the heat insulation spacer may be 10 W/(m·K) or less. In this case, by setting the thermal conductivity of the heat insulation spacer to 10 W/(m·K) or less, the inflow of heat from the support portion to the relay board can be more reliably suppressed.

(3) in (1) or (2) above, the relay board may have signal wiring and ground wiring. The ground wiring may be electrically connected to the metal stem at the first end in the first direction of the relay board, and may be electrically connected to the optical semiconductor element via the bonding wire at the second end opposite to the first end in the first direction of the relay board.

(4) in any of (1) to (3) above, the contact area between the relay board and the heat insulation spacer may be smaller than the area of the bottom surface of the relay board. In this case, the space is formed between a portion of the bottom surface of the relay board and the support portion. Therefore, the inflow of heat from the support portion to the relay board can be more effectively suppressed.

### Details of Embodiments of Present Disclosure

Hereinafter, a specific example of the optical transmission module according to the embodiment will be described with reference to the drawings. In the description of the drawings, the same or corresponding elements are denoted by the same reference numerals, and overlapping description will be omitted as appropriate. In some drawings, some portions may be simplified or exaggerated for ease of understanding, and dimensional ratios, directions, and the like are not limited to those illustrated in the drawings.

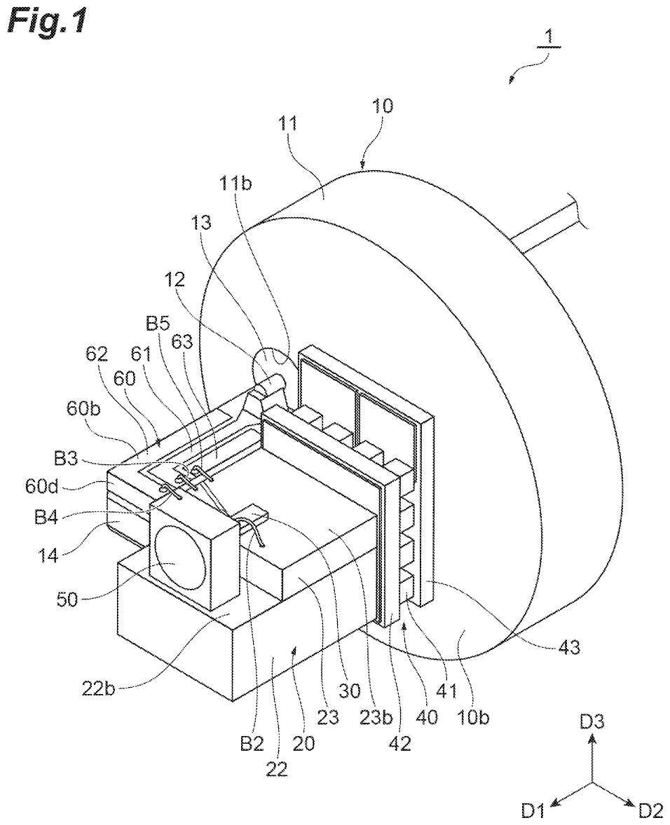

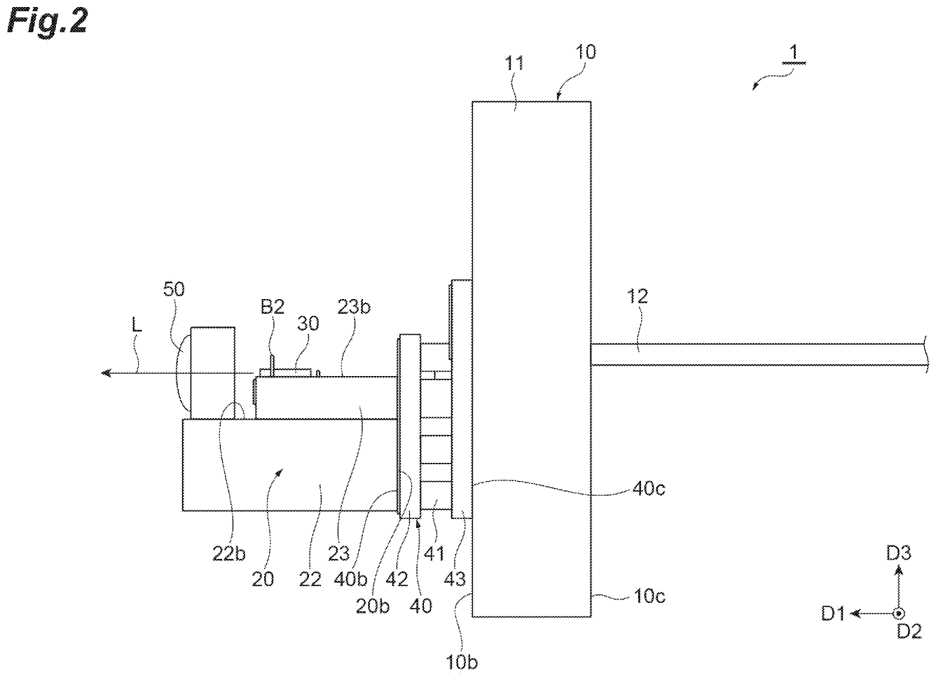

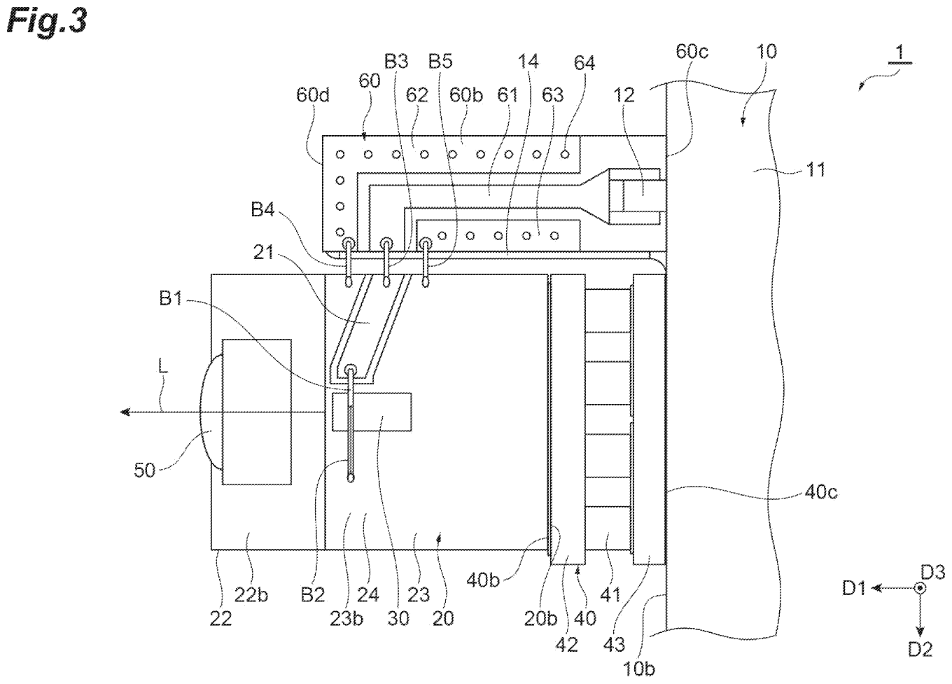

FIG. 1 is a perspective view illustrating an optical transmission module 1 according to the present embodiment. FIG. 2 is a side view illustrating the optical transmission module 1. FIG. 3 is a plan view of the optical transmission module 1. The optical transmission module 1 converts electrical signals into optical signals. The optical transmission module 1 outputs the optical signal along, for example, a first direction D1. For example, the optical transmission module 1 includes a metal stem 10, a dielectric block 20, an optical semiconductor element 30, a temperature control element 40, a lens 50, and a relay board 60. For example, the optical transmission module 1 may further include a cylindrical housing (not illustrated), and the optical semiconductor element 30 may be hermetically sealed between the housing and the metal stem 10. The optical transmission module 1 is, for example, a coaxial transmitter optical sub-assembly (TOSA).

The metal stem 10 includes, for example, a base 11, a signal terminal 12, and a fixed member 13. The base 11 has a disk shape. The base 11 is made of metal. Accordingly, the base 11 transfers the heat from the temperature control element 40 to the outside of the optical transmission module 1. For example, the material of the base 11 may contain at least any of soft iron, cold rolled steel, and an iron (Fe)-nickel (Ni)-cobalt (Co) alloy (Kovar). The base 11 has a penetrating hole 11b penetrating the base 11 in the first direction D1. The signal terminal 12 extends in the first direction D1 while penetrating via the penetrating hole 11b. The signal terminal 12 has, as an example, a cylindrical shape with a central axis extending along the first direction D1. The fixed member 13 is filled into the penetrating hole 11b which penetrates the signal terminal 12. The metal stem 10 is, for example, configured to be at a ground potential when the optical transmission module 1 is mounted on an optical transceiver or a circuit board of an optical communication device.

The signal terminal 12 is fixed to the base 11 by the fixed member 13 filled in the penetrating hole 11b. The signal terminal 12 has conductivity. The signal terminal 12 is made of, for example, metal. The signal terminal 12 is insulated from the base 11 by the fixed member 13. The fixed member 13 is, as an example, a glass material for sealing. It is noted that in each of FIGS. 1, 2, and 3, the optical transmission module 1 has one signal terminal 12. However, depending on the function or the like of the optical transmission module 1, the terminal similar to the signal terminal 12 may be provided. In this way, the optical transmission module 1 may have a plurality of terminals. The terminal is, for example, a terminal for supplying the power supply voltage to the optical semiconductor element 30 or the temperature control element 40, a terminal for providing a reference potential, or a terminal for transmitting the control electrical signal.

The metal stem 10 has a first surface 10b on which the temperature control element 40 is mounted, and a second surface 10c facing in the opposite direction to the first surface 10b. As an example, each of the first surface 10b and the second surface 10c is a flat surface. For example, the first surface 10b extends in both a second direction D2 that intersects the first direction D1, and a third direction D3 that intersects both the first direction D1 and the second direction D2. For example, the first direction D1, the second direction D2, and the third direction D3 are orthogonal to each other. One end of the signal terminal 12 protrudes from the first surface 10b in the first direction D1. Further, the other end of the signal terminal 12 protrudes from the second surface 10c in the direction opposite to the one end of the signal terminal 12. The signal terminal 12 can transmit the electrical signal between the first surface 10b and the second surface 10c while being insulated from the base 11.

The optical transmission module 1 further includes a support portion 14 extending from the metal stem 10 in the first direction D1. The support portion 14 protrudes from the first surface 10b of the metal stem 10 in the first direction D1. It is noted that the member different from the metal stem 10 may be connected to the metal stem 10 as the support portion 14. When the support portion 14 is a member different from the metal stem 10, the position of the support portion 14 connected to the first surface 10b can be changed. For example, the support portion 14 is a rectangular parallelepiped-shaped block extending in the first direction D1. The support portion 14 may be adhered to the first surface 10b. For example, the support portion 14 has an adhesive surface facing the first surface 10b, and is fixed to the metal stem 10 by bonding the adhesive surface to the first surface 10b. The support portion 14 is made of metal. As an example, the support portion 14 is electrically connected to the metal stem 10 via the conductive adhesive.

The dielectric block 20 holds, for example, the optical semiconductor element 30 and the lens 50. The dielectric block 20 is made of a dielectric material. As an example, the dielectric block 20 is made of ceramics. The ceramic is, for example, aluminum nitride. Since the dielectric block 20 is made of ceramics, the deterioration of the frequency characteristics of the electrical signal propagating through a signal pattern 21 on a semiconductor mounting surface 23b of the dielectric block 20, which will be described later, can be suppressed.

The dielectric block 20 includes, for example, a submount 22 and a carrier 23 mounted on the submount 22. The submount 22 has an optical mounting surface 22b. The optical mounting surface 22b extends in both the first direction D1 and the second direction D2. The optical mounting surface 22b is, for example, a flat surface. The carrier 23 is mounted, for example, on the optical mounting surface 22b. The carrier 23 has the semiconductor mounting surface 23b. The semiconductor mounting surface 23b extends in both the first direction D1 and the second direction D2.

For example, the semiconductor mounting surface 23b is a flat surface. The position of the optical mounting surface 22b in the third direction D3 and the position of the semiconductor mounting surface 23b in the third direction D3 are different from each other. For example, the height of the semiconductor mounting surface 23b in the third direction D3 is higher than the height of the optical mounting surface 22b in the third direction D3. In the following, in the third direction D3, the direction in which the semiconductor mounting surface 23b is located relative to the optical mounting surface 22b is expressed as “high”, and the direction in which the optical mounting surface 22b is located relative to the semiconductor mounting surface 23b is expressed as “low”. The difference in height between the semiconductor mounting surface 23b and the optical mounting surface 22b corresponds to the length (thickness) of the carrier 23 in the third direction D3. The dielectric block 20 further has a heat conduction surface 20b. The heat conduction surface 20b extends along the second direction D2 and the third direction D3. As an example, the heat conduction surface 20b is the flat surface.

The optical semiconductor element 30 is mounted on the semiconductor mounting surface 23b. Furthermore, a capacitor, a resistor, or the like may be further mounted on the semiconductor mounting surface 23b. For example, a conductive pattern is formed on the semiconductor mounting surface 23b. For example, a signal pattern 21 and a ground pattern 24 are formed as conductive patterns on the semiconductor mounting surface 23b. Each of the signal pattern 21 and a ground pattern 24 is made of a conductive material. The ground pattern 24 is formed, for example, so as to surround the signal pattern 21 in plan view of the semiconductor mounting surface 23b. The signal pattern 21 surrounded by the ground pattern 24 is, for example, a transmission line that transmits the electrical signal input from the signal terminal 12 to the optical semiconductor element 30. Since the signal pattern 21 is the transmission line, the transmission characteristics of the electrical signal to the optical semiconductor element 30 can be improved. The optical semiconductor element 30 is provided on, for example, the ground pattern 24.

In addition to the optical semiconductor element 30, for example, at least any of a termination resistor, a termination capacitor, a bypass capacitor, and a terminal may be mounted on the semiconductor mounting surface 23b. Conductive patterns other than the signal pattern 21 and the ground pattern 24 may be formed on the semiconductor mounting surface 23b. On the semiconductor mounting surface 23b, the plurality of conductive patterns, the termination resistor, the termination capacitor, and the bypass capacitor may constitute the peripheral circuit for causing the optical semiconductor element 30 to perform the predetermined operation. For example, the termination resistor and the termination capacitor constitute a termination circuit for electrically terminating the above-mentioned transmission line.

The lens 50 is mounted on the optical mounting surface 22b. The optical mounting surface 22b is provided at the position lower than the semiconductor mounting surface 23b so that, when the lens 50 is mounted, the optical axis of the lens 50 coincides with the optical axis L of the optical signal output from the optical semiconductor element 30 in the third direction D3. The position of the optical mounting surface 22b is set lower than the semiconductor mounting surface 23b, taking into account the size of the lens 50. Accordingly, when the lens 50 is mounted on the optical mounting surface 22b, the optical signal output from the optical semiconductor element 30 mounted on the semiconductor mounting surface 23b is suitably incident on the lens 50. As described above, the distance between the semiconductor mounting surface 23b and the optical mounting surface 22b is set according to the outer shape of the lens 50. The distance can be adjusted by changing the thickness of, for example, the carrier 23.

For example, the optical mounting surface 22b is formed to be parallel to the semiconductor mounting surface 23b. In this case, the optical signal (beam) output from the optical semiconductor element 30 can be allowed to be perpendicularly incident on the incident surface of the lens 50, which is provided perpendicularly to the optical mounting surface 22b. For example, the position of the optical mounting surface 22b in the third direction D3 and the position of the semiconductor mounting surface 23b in the third direction D3 are determined depending on the distance from the semiconductor mounting surface 23b to the emission point of the optical signal of the optical semiconductor element 30 in the third direction D3 and the distance from the optical mounting surface 22b to the central axis (optical axis) of the lens 50. For example, the lens 50 is fixed to the optical mounting surface 22b by the curable resin. It is noted that the distance from the optical mounting surface 22b to the central axis (optical axis) of the lens 50 may be adjusted depending on the thickness of the curable resin.

The semiconductor mounting surface 23b on which the optical semiconductor element 30 is mounted and the optical mounting surface 22b on which the lens 50 is mounted are, for example, surfaces perpendicular to the third direction D3, that is, parallel to the first direction D1. As an example, the orientation of the optical mounting surface 22b and the orientation of the semiconductor mounting surface 23b are the same. In this case, the optical semiconductor element 30 and the lens 50 can be mounted on the dielectric block 20 from the same direction. The optical semiconductor element 30 is mounted on the semiconductor mounting surface 23b so as to output the optical signal along the first direction D1. That is, the optical semiconductor element 30 is mounted on the semiconductor mounting surface 23b so that the optical axis L of the output optical signal is along the first direction D1.

The optical semiconductor element 30 converts the electrical signal into the optical signal. The electrical signal that the optical semiconductor element 30 converts into the optical signal includes, for example, the high frequency component of 30 GHz or higher. The optical semiconductor element 30 generates the optical signal modulated by the electrical signal input from the signal terminal 12 via the signal pattern 21. The optical semiconductor element 30 emits the optical signal along the first direction D1. Therefore, the optical axis L of the optical signal extends in the first direction D1. The optical semiconductor element 30 includes, for example, the laser diode or an electroabsorption optical modulator. When the optical semiconductor element 30 is the electroabsorption optical modulator, the optical semiconductor element 30 may be provided on the same semiconductor chip as the laser diode that generates the modulated light.

For example, the optical semiconductor element 30 may be a modulator integrated semiconductor laser that integrates the electroabsorption optical modulator. The optical axis L is provided at the position separated from the semiconductor mounting surface 23b by a predetermined distance in the third direction D3 according to the structure of the optical semiconductor element 30. The optical semiconductor element 30 is connected to the signal pattern 21 via a bonding wire B1. The optical semiconductor element 30 is connected to the termination circuit (not illustrated) via, for example, a bonding wire B2 and is connected to the ground pattern 24 via the termination circuit. Therefore, the signal pattern 21 is connected to the termination circuit via the bonding wire B1 and the bonding wire B2.

Next, the temperature control element 40 will be described. The temperature control element 40 is disposed between the metal stem 10 and the heat conduction surface 20b of the dielectric block 20. The temperature control element 40 has a temperature control surface 40b connected to the heat conduction surface 20b of the dielectric block 20. The dielectric block 20 is cooled or heated by the temperature control element 40 by connecting the heat conduction surface 20b to the temperature control surface 40b of the temperature control element 40. For example, the heat conduction surface 20b and the temperature control surface 40b are provided so as to face each other and are fixed in surface contact with each other. Accordingly, heat is efficiently transferred between the dielectric block 20 and the temperature control element 40. That is, the temperature of the dielectric block 20 is controlled by the heating or cooling function of the temperature control element 40, which will be described later.

The temperature control element 40 is, for example, a thermoelectric cooler (TEC). The temperature control element 40 includes a plurality of Peltier elements 41 that are Peltier bonded. For example, the temperature control element 40 cools or heats the components attached to the temperature control surface 40b by being supplied with electric power from the terminal (not illustrated) provided on the metal stem 10. For example, in order to maintain the peak wavelength of the optical signal generated by the optical semiconductor element 30 at the predetermined value when optical wavelength multiplexing communication is performed, the temperature of the optical semiconductor element 30 is required to maintain the predetermined laser temperature. For example, when the external temperature of the optical transmission module 1 is higher than the predetermined laser temperature, the temperature control element 40 cools the temperature control surface 40b to maintain the temperature of the optical semiconductor element 30 at the predetermined laser temperature (cooling function). When the external temperature of the optical transmission module 1 is lower than the predetermined laser temperature, the temperature control element 40 heats the temperature control surface 40b to maintain the temperature of the optical semiconductor element 30 at the predetermined laser temperature (heating function).

The temperature control element 40 is provided between the first surface 10b of the metal stem 10 and the heat conduction surface 20b of the dielectric block 20. For example, the heat conduction surface 20b is fixed to the temperature control surface 40b with the adhesive. The temperature control element 40 has a heat dissipation surface 40c facing opposite to the temperature control surface 40b. The heat dissipation surface 40c is fixed to the first surface 10b with the adhesive. At this time, since the heat dissipation surface 40c and the first surface 10b are in surface contact with each other, heat is efficiently transferred between the dielectric block 20 and the metal stem 10. The heat dissipation surface 40c dissipates the absorbed heat when the temperature control element 40 performs heat absorption (cooling function) on the temperature control surface 40b, and absorbs the dissipated heat when the temperature control element 40 performs heat dissipation (heating function) on the temperature control surface 40b. For example, the temperature control surface 40b and the heat dissipation surface 40c extend parallel to each other. In this case, the optical axis L can be allowed to be perpendicular to the first surface 10b of the metal stem 10.

The temperature control element 40 includes a first substrate 42, a second substrate 43, and a plurality of Peltier elements 41. The plurality of Peltier elements 41 are provided between the first substrate 42 and the second substrate 43. The first substrate 42 has the temperature control surface 40b, and the second substrate 43 has the heat dissipation surface 40c. The current is supplied to the Peltier element 41. By supplying current to the plurality of Peltier elements 41 in the predetermined direction, the heat absorbed in the first substrate 42 is dissipated in the second substrate 43, and thus, the dielectric block 20 connected to the temperature control surface 40b is cooled. By supplying current to the plurality of Peltier elements 41 in the direction opposite to the predetermined direction, the heat absorbed in the second substrate 43 is dissipated in the first substrate 42, and thus, the dielectric block 20 connected to the temperature control surface 40b is heated.

Next, the lens 50 will be described. The lens 50 is, for example, the optical lens into which the optical signal emitted from the optical semiconductor element 30 is incident. The lens 50 is made of, for example, optical glass. The lens 50 receives the optical signal emitted from the optical semiconductor element 30 and outputs the optical signal as parallel light. For example, the lens 50 is fixed to the optical mounting surface 22b by adhesive. This adhesive is made of, for example, the ultraviolet curing resin. For example, the lens 50 is fixed to the optical mounting surface 22b in the state in which the optical axis of the lens 50 is aligned to match with the optical axis L of the optical signal output from the optical semiconductor element 30 in the second direction D2 and the third direction D3.

The lens 50 has the bottom surface facing the optical mounting surface 22b. For example, the adhesive before curing is applied between the bottom surface of the lens 50 and the optical mounting surface 22b. Further, after the alignment described above, the adhesive is heated and irradiated with ultraviolet rays to cure the adhesive, so that the lens 50 is fixed to the optical mounting surface 22b. It is noted that, since the optical signal output from the optical semiconductor element 30 spreads in the second direction D2 and the third direction D3 as separated from the optical semiconductor element 30, the position of the lens 50 in the first direction D1 may be aligned while the intensity of the parallel light output from the lens 50 is monitored.

As described above, by fixing the temperature control element 40 to the metal stem 10 and fixing the dielectric block 20 to the temperature control element 40, the optical semiconductor element 30 and the lens 50 mounted on the dielectric block 20 are fixed and held relative to the metal stem 10. Further, the temperature of the optical semiconductor element 30 mounted on the dielectric block 20 is adjusted by the cooling or heating function of the temperature control element 40 via the dielectric block 20. It is noted that the dielectric block 20, the optical semiconductor element 30, the temperature control element 40, the lens 50, and the relay board 60 are accommodated inside the cylindrical casing, and the inside of the casing is hermetically sealed by bonding the casing to the first surface 10b.

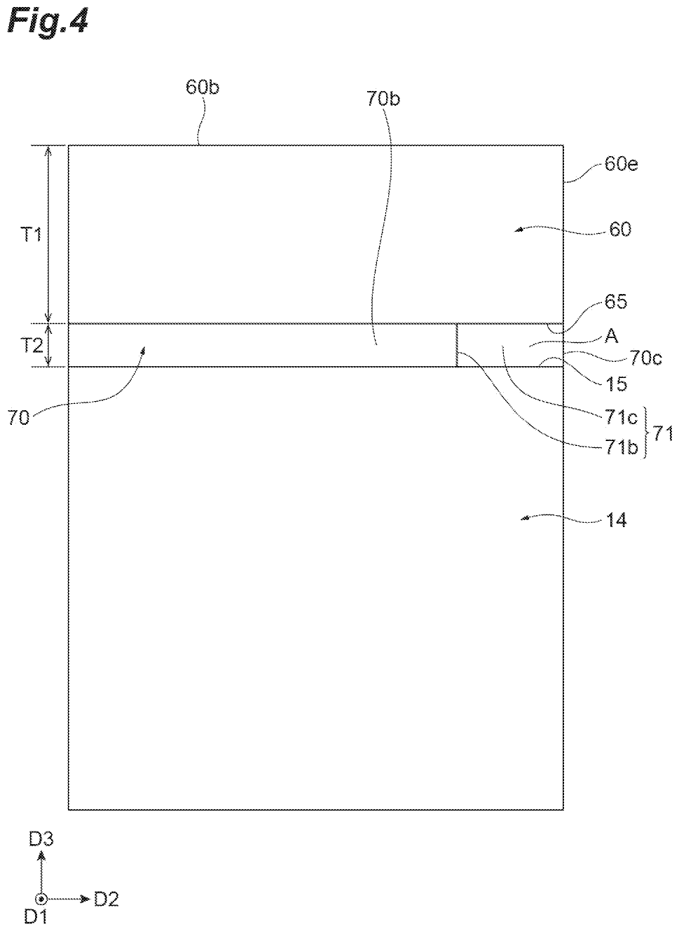

Next, the relay board 60 will be described. For example, the material of the relay board 60 is aluminum nitride (AlN) or alumina. The relay board 60 is provided to electrically connect the signal terminal 12 to the optical semiconductor element 30. The relay board 60 transmits the electrical signal from the signal terminal 12 to the optical semiconductor element 30. The relay board 60 extends along the first direction D1. The length of the relay board 60 in the first direction D1 is, for example, 2 mm or more and 5 mm or less. The relay board 60 has an upper surface 60b extending in both the first direction D1 and the second direction D2. The relay board 60 has, for example, a signal wiring 61, a first ground wiring 62 (ground wiring), and a second ground wiring 63 (ground wiring) on the upper surface 60b. The relay board 60 has an end face 60e extending in the first direction D1. The end face 60e is an end face close to the dielectric block 20 (refer to FIG. 4).

The signal wiring 61, the first ground wiring 62, and the second ground wiring 63 are made of, for example, metal. The signal wiring 61 is connected to the signal terminal 12. The first ground wiring 62 and the second ground wiring 63 are grounded. Since the waveform quality of the electrical signal from the signal terminal 12 is not deteriorated, the signal wiring 61 is formed to constitute the transmission line together with the first ground wiring 62 and the second ground wiring 63. For example, the signal wiring 61 extends in the first direction D1 and is formed to be interposed between the first ground wiring 62 and the second ground wiring 63 in the second direction D2. One end of the signal wiring 61 is electrically connected to the signal terminal 12, and the other end of the signal wiring 61 is electrically connected to the signal pattern 21.

More specifically, for example, the signal wiring 61 is connected to the signal pattern 21 via a bonding wire B3. The first ground wiring 62 is connected to the ground pattern 24 via a bonding wire B4. The second ground wiring 63 is connected to the ground pattern 24 via a bonding wire B5. The first ground wiring 62 and the second ground wiring 63 are electrically connected to the metal stem 10 at a first end 60c of the relay board 60 in the first direction D1. The first ground wiring 62 and the second ground wiring 63 are electrically connected to the ground pattern 24 via the bonding wires B4 and B5 at a second end 60d opposite to the first end 60c of the relay board 60 in the first direction D1.

Each of the bonding wires B3, B4, and B5 extends, for example, along the second direction D2. For example, the positions of the bonding wires B3, B4, and B5 in the second direction D2 are the same. The lengths of the bonding wires B3, B4, and B5 are preferably set short in order to reduce a parasitic inductance. For example, the lengths of the bonding wires B3, B4, and B5 are the same. The height of the upper surface 60b of the relay board 60 (position in the third direction D3) may be close to the height of the semiconductor mounting surface 23b of the dielectric block 20 (position in the third direction D3). In this case, the lengths of the bonding wires B3, B4, and B5 can be shortened.

By the way, since the relay board 60 is connected to the dielectric block 20 via the bonding wires B3, B4, and B5, heat may flow from the relay board 60 to the dielectric block 20 via the bonding wires B3, B4, and B5. For example, when the optical semiconductor element 30 is cooled by the temperature control element 40, when heat flows into the dielectric block 20 from the relay board 60, the power consumption of the temperature control element 40 required for the cooling function increases. Therefore, in order to efficiently control the temperature of the optical semiconductor element 30, the inflow of heat from the relay board 60 to the dielectric block 20 may be minimize. By suppressing the inflow of heat, the power consumption required for the temperature control can be reduced.

For example, the end (one end) of the signal wiring 61 is connected to one end of the signal terminal 12 protruding from the first surface 10b. The end of the signal wiring 61 and one end of the signal terminal 12 may be connected by solder or may be connected by wire bonding. The end of the signal wiring 61 and one end of the signal terminal 12 may be close to each other from the viewpoint of signal transmission. For example, the position of the support portion 14 on the first surface 10b may be determined so that the end of the signal wiring 61 and one end of the signal terminal 12 are close to each other.

FIG. 4 is a side view schematically illustrating the support portion 14 and the relay board 60. As illustrated in FIG. 4, the optical transmission module 1 includes a heat insulation spacer 70 between the support portion 14 and the relay board 60. The relay board 60 is supported by the support portion 14 via the heat insulation spacer 70. Compared to the case where the relay board 60 is directly connected to the support portion 14, the support portion 14 and the relay board 60 are thermally isolated from each other by the heat insulation spacer 70. For this reason, as described later, the heat insulation spacer 70 may be made of a material with low thermal conductivity. Generally, since metal has high thermal conductivity, the heat insulation spacer 70 is made of a material other than metal. For example, the heat insulation spacer 70 has an insulation property. In this case, the support portion 14 is not directly electrically connected to the relay board 60. The heat insulation spacer 70 may be a solid material. Further, the heat insulation spacer 70 may be in a form of the paste. As an example, the heat insulation spacer 70 has a flat plate shape. The heat insulation spacer 70 may define an insulated space A between the relay board 60 and the support portion 14. The insulated space A will be described later.

For example, the heat insulation spacer 70 extends in both the first direction D1 and the second direction D2 and has the thickness in the third direction D3. For example, the thickness of the heat insulation spacer 70 in the third direction D3 is smaller than the length of the heat insulation spacer 70 in each of the first direction D1 and the second direction D2. For example, a thickness T1 of the relay board 60 is larger than a thickness T2 of the heat insulation spacer 70. As an example, the thickness T1 of the relay board 60 is 250 μm. The thickness T2 of the heat insulation spacer 70 is, for example, 100 μm or more and 150 μm or less when the heat insulation spacer 70 is the solid substance, and is several tens of μm when the heat insulation spacer 70 is in the form of the paste. The thickness T2 of the heat insulation spacer 70 may be as thick as possible, for example, within an allowable range due to the size constraints of the optical transmission module 1. By increasing the thickness of the heat insulation spacer 70, the thermal resistance between the support portion 14 and the relay board 60 increases, and the thermal separation (insulation property) between the support portion 14 and the relay board 60 improves.

When the heat insulation spacer 70 is a solid material, for example, the heat insulation spacer 70 is fixed to the support portion 14 and the relay board 60 with the adhesive. When the heat insulation spacer 70 is in the form of the paste, the heat insulation spacer 70 itself may be fixed to the support portion 14 and the relay board 60 by adhering to the support portion 14 and the relay board 60. In this manner, by fixing the relay board 60 to the support portion 14, the relay board 60 is reliably supported by the support portion 14. The heat insulation spacer 70 is made of, for example, quartz, glass, Teflon (registered trademark), or resin (plastic, for example). Further, the heat insulation spacer 70 may be made of a non-conductive resin.

For example, the heat insulation spacer 70 may be configured by a flexible printed circuit (FPC) or a printed circuit board (PCB). The thermal conductivity of the heat insulation spacer 70 is lower than the thermal conductivity of the support portion 14 and lower than the thermal conductivity of the relay board 60. For example, the thermal conductivity of the heat insulation spacer 70 is 10 W/(m·K) or less. When the heat insulation spacer 70 is made of quartz, the thermal conductivity of the heat insulation spacer 70 is 1.4 W/(m·K) or more and 1.9 W/(m·K) or less, and when the heat insulation spacer 70 is made of glass, the thermal conductivity of the heat insulation spacer 70 is about 1.0 W/(m·K). When the heat insulation spacer 70 is made of Teflon (registered trademark), the thermal conductivity of the heat insulation spacer 70 is about 0.25 W/(m·K), and when the heat insulation spacer 70 is made of resin (or plastic), the thermal conductivity of the heat insulation spacer 70 is 0.1 W/(m·K) or more and 0.3 W/(m·K) or less. For example, the thermal conductivity of aluminum nitride is 170 to 230 W/(m·K). The thermal conductivity of the heat insulation spacer 70 is lower than the thermal conductivity of aluminum nitride by one digit or more.

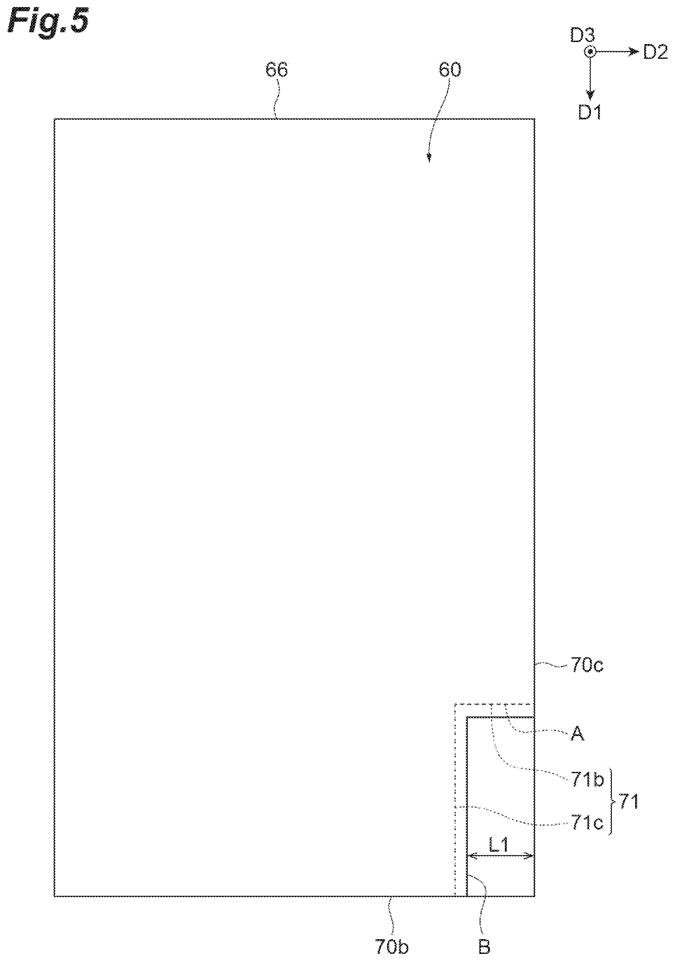

FIG. 5 is a plan view of the relay board 60 viewed along the third direction D3. As illustrated in FIG. 5, viewing the relay board 60 along the third direction D3 is also referred to as the “planar view of the relay board 60”. As illustrated in FIGS. 4 and 5, the relay board 60 has a wire connection region B to which one end of each of the bonding wires B3, B4, and B5 is connected. The wire connection region B is a virtual region on the upper surface 60b of the relay board 60 that includes one end of each of the bonding wires B3, B4, and B5 illustrated in FIG. 3. The wire connection region B has, for example, a rectangular shape. The wire connection region B may include one end of each of the bonding wires B3, B4, and B5 inside the wire connection region B in a predetermined distance or more. For example, the predetermined distance is 100 μm.

The side of the wire connection region B extending in the first direction D1 and close to the dielectric block 20 overlaps the end face 60e of the relay board 60 in plan view. The wire connection region B has, for example, a length (first distance) L1 in the second direction D2. The insulated space A is a space formed between the relay board 60 and the support portion 14. The insulated space A is formed by removing the heat insulation spacer 70 in this portion. As illustrated in FIG. 5, in plan view of the relay board 60, when the insulated space A is seen through, the insulated space A is formed to include the wire connection region B. It is noted that, in plan view of the relay board 60, the insulated space A and the wire connection region B have the same shape and may overlap each other. By forming the insulated space A, the contact area between the relay board 60 and the heat insulation spacer 70 is smaller than the area of a bottom surface 65 of the relay board 60. Therefore, the thermal resistance between the relay board 60 and the support portion 14 is larger than the thermal resistance in the case where the insulated space A is not provided, and an insulation property between the support portion 14 and the relay board 60 is improved. That is, since heat is conducted to one end of each of the bonding wires B3, B4, and B5 through the heat insulation spacer 70 around the insulated space A, the heat is less likely to be transferred from the support portion 14 to the bonding wires B3, B4, and B5, compared to the case where the insulated space A is not provided.

The insulated space A is defined by, for example, a removed portion 71 of the heat insulation spacer 70, the bottom surface 65 of the relay board 60, and an upper surface 15 of the support portion 14. The removed portion 71 is defined by a first inner surface 71b and a second inner surface 71c of the heat insulation spacer 70. The heat insulation spacer 70 has an end face 70c extending in the first direction D1 and an end face 70b extending in the second direction D2 in plan view from the third direction D3. The end face 70c is close to the dielectric block 20, and the end face 70b is located on the opposite side of the metal stem 10. The first inner surface 71b is parallel to the end face 70b of the heat insulation spacer 70 and is located inside the end face 70b in the first direction D1. The second inner surface 71c is parallel to the end face 70c of the heat insulation spacer 70 and located inside the end face 70c in the second direction D2. For example, the length of the second inner surface 71c in the first direction D1 is larger than the length of the first inner surface 71b in the second direction D2. In plan view from the third direction D3, the end face 70c of the heat insulation spacer 70 overlaps the end face 60e of the relay board 60. It is noted that the end face 70c of the heat insulation spacer 70 may not need to overlap the end face 60e of the relay board 60.

The relay board 60 has a side surface 66 that connects to the metal stem 10. The side surface 66 extends in both the second direction D2 and the third direction D3. For example, the side surface 66 is metalized. The relay board 60 is electrically connected to the metal stem 10 via the side surface 66. Accordingly, the ground wiring can be configured on the relay board 60. For example, the bottom surface 65 of the relay board 60 may be metalized, and the metalized side surfaces 66 and the metalized bottom surface 65 may be electrically connected to each other. Furthermore, the metallized bottom surface 65 and the first ground wiring 62 and the second ground wiring 63 formed on the upper surface 60b may be electrically connected by a through via 64 or the like. Accordingly, the first ground wiring 62 and the second ground wiring 63 are electrically connected to the metal stem 10 having the ground potential, and the transmission line can be formed on the upper surface 60b. It is noted that the bottom surface 65 may not be metalized over the entire surface, but may have the ground wiring formed partially so as to include the portion necessary for connection with the through via 64. Accordingly, the flow of heat into and out of a region between the metal stem 10 and the bottom surface 65 via the ground wiring can be reduced.

Next, the functions and effects obtained from the optical transmission module 1 according to this embodiment will be described. The optical transmission module 1 includes the metal stem 10 having the signal terminal 12 and the support portion 14, and the dielectric block 20. The dielectric block 20 has the semiconductor mounting surface 23b and the heat conduction surface 20b. The temperature control element 40 is disposed between the metal stem 10 and the heat conduction surface 20b of the dielectric block 20, and the optical semiconductor element 30 is mounted on the semiconductor mounting surface 23b of the dielectric block 20. The optical transmission module 1 includes the relay board 60 electrically connected to the optical semiconductor element 30 and the heat insulation spacer 70 disposed between the relay board 60 and the support portion 14. The thermal conductivity of the heat insulation spacer 70 is lower than the thermal conductivity of the support portion 14 and lower than the thermal conductivity of the relay board 60. Therefore, since the inflow of heat from the support portion 14 of the metal stem 10 to the relay board 60 is reduced by the heat insulation spacer 70, the inflow of heat from the relay board 60 to the dielectric block 20 can be reduced. Therefore, by suppressing the inflow of heat from the support portion 14 of the metal stem 10 to the relay board 60, the temperature of the optical element such as the optical semiconductor element 30 can be efficiently controlled by the temperature control element 40. Accordingly, the power consumption required for temperature control can be reduced.

In this embodiment, the thermal conductivity of the heat insulation spacer 70 may be 10 W/(m·K) or less. In this case, by setting the thermal conductivity of the heat insulation spacer 70 to 10 W/(m·K) or less, the inflow of heat from the support portion 14 to the relay board 60 can be more reliably suppressed.

In the related art, solder may be sometimes interposed between the support portion 14 and the relay board 60 instead of the heat insulation spacer 70. Hereinafter, the thermal resistances of the optical transmission module according to the comparative example in which solder is interposed between the support portion 14 and the relay board 60 and the optical transmission module 1 according to the present embodiment will be compared. In comparison of this thermal resistance, the thickness T1 of the relay board 60 is set to be 2.5×10⁻⁴ m (250 μm), and the thickness t (length in the third direction D3) of the solder is set to be 1.0×10⁻⁵ m (10 μm). The length of the insulated space A in the first direction D1 when viewed from the third direction D3 is set to be 1.0×10⁻³ m (1 mm), and the length of the insulated space A in the second direction D2 when viewed from the third direction D3 is set to be 2.0×10⁻⁴ m (0.2 mm), and an area S of the insulated space A when viewed from the third direction D3 is set to be 2.0×10⁻⁷ m². In this case, the thermal resistance between the upper surface 60b and the bottom surface 65 of the relay board 60 is expressed by the following equation (1).

$$\begin{matrix}Thermal resistance = T ( or t ) / ( S \times thermal conductivity ) \\ = 2.5 \times {10}^{- 4} ( or 1. \times {10}^{- 5} ) / ( 2. \times {10}^{- 7} \times \\ thermal conductivity )\end{matrix} \qquad ( 1 )$$

When the relay board 60 is made of aluminum nitride (AlN), the thermal conductivity of aluminum nitride is 170 [W/(m·K)], so that the thermal resistance of the relay board 60 is 7.35 [K/W]. Furthermore, when the relay board 60 is made of alumina, since the thermal conductivity of alumina is 18 [W/(m·K)], the thermal resistance of the relay board 60 becomes 69.4 [K/W]. Since the thermal conductivity of the solder is 57.3, the thermal resistance of the solder in the optical transmission module of Comparative Example becomes 0.873 [K/W]. On the other hand, the optical transmission module 1 according to this embodiment includes the heat insulation spacer 70 instead of the solder. As an example, when the heat insulation spacer 70 is made of ultraviolet curing resin, since the thermal conductivity of the ultraviolet curing resin is 0.7 [W/(m·K)], compared to Comparative Example including solder, the thermal resistance can be increased significantly. As a specific example, the same thermal resistance as the thermal resistance of the doubled thickness of the relay board 60, which is an alumina board, can be obtained.

In this embodiment, the relay board 60 may have the signal wiring 61, the first ground wiring 62, and the second ground wiring 63. The first ground wiring 62 and the second ground wiring 63 may be electrically connected to the metal stem 10 at the first end 60c of the relay board 60 in the first direction D1, and may be electrically connected to the optical semiconductor element 30 via the bonding wires B3, B4, and B5 at the second end 60d opposite to the first end 60c of the relay board 60 in the first direction D1.

In this embodiment, the contact area between the relay board 60 and the heat insulation spacer 70 may be smaller than the area of the bottom surface 65 of the relay board 60. In this case, the space (insulated space A) is formed between a portion of the bottom surface 65 of the relay board 60 and the support portion 14. Therefore, by forming the space between the portion of the bottom surface 65 of the relay board 60 and the support portion 14, the inflow of heat from the support portion 14 to the relay board 60 can be more effectively reduced.

Hereinafter, optical transmission modules according to various modifications will be described. In various modifications described later, the portion of the configuration of the optical transmission module is the same as the portion of the configuration of the optical transmission module 1 described above. Therefore, hereinafter, the description that overlaps the description of the optical transmission module 1 will be denoted by the same reference numerals and omitted as appropriate.

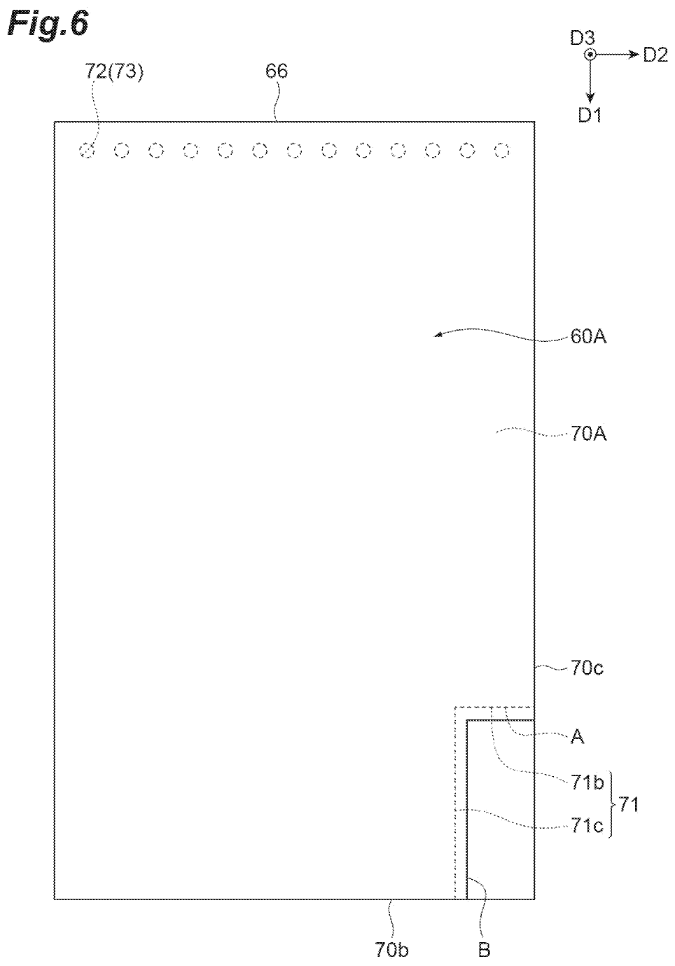

FIG. 6 is a plan view illustrating a relay board 60A of the optical transmission module according to Modified Example 1. In the embodiment described above, the optical transmission module 1 is described which includes the relay board 60 of which the side surface 66 is metalized. On the other hand, the optical transmission module according to Modified Example 1 has a heat insulation spacer 70A, and the heat insulation spacer 70A has a via 72 which is a conductive portion penetrating the heat insulation spacer 70A in the third direction D3.

The via 72 is provided to electrically connect the support portion 14 to the bottom surface 65 of the relay board 60A. In this case, metallization of the side surface 66 can be made unnecessary. The heat insulation spacer 70A has, for example, a plurality of vias 72. In this case, the plurality of vias 72 are aligned along the second direction D2. The support portion 14 is electrically connected to the metal stem 10 even when the support portion is provided so as to protrude from the metal stem 10 or when the support portion is connected to the metal stem 10 as a different member. Therefore, by electrically connecting the bottom surface 65 of the relay board 60A to the support portion 14, the transmission line can be configured on the upper surface 60b of the relay board 60. Although the plurality of vias 72 conduct heat, the area of the plurality of vias 72 is suppressed to, for example, 1/100 or less compared to the area of the bottom surface 65. Therefore, the inflow of heat from the support portion 14 to the upper surface 60b of the relay board 60A can be significantly reduced. Further, in Modified Example 1, instead of the via 72, the heat insulation spacer 70A may have a through hole 73 penetrating the heat insulation spacer 70A in the third direction D3 and the pin inserted into the through hole 73. In this case as well, the same functions and effects as in the case where the via 72 is provided can be obtained.

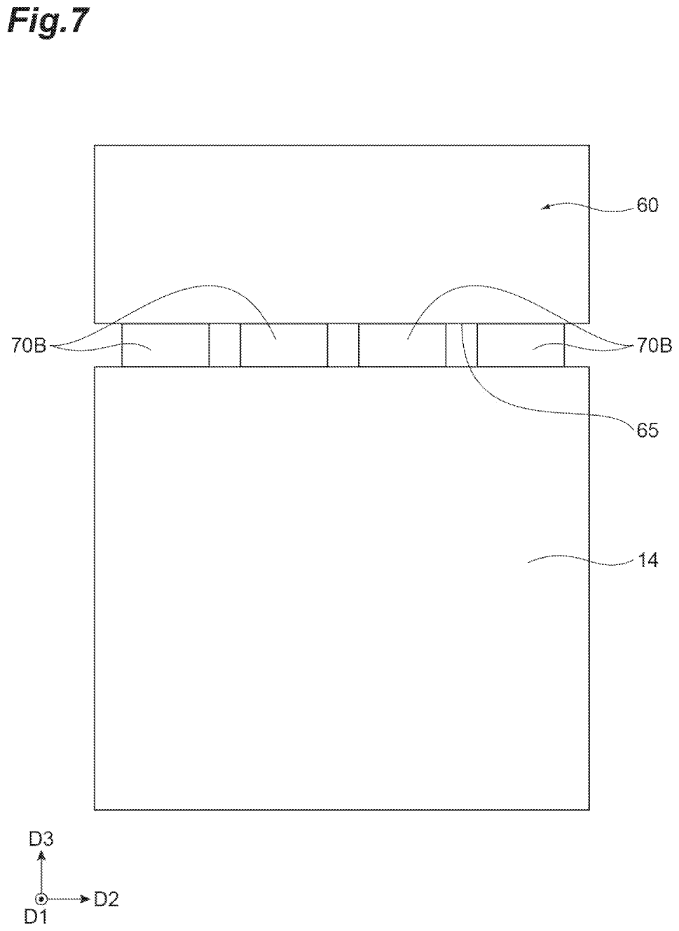

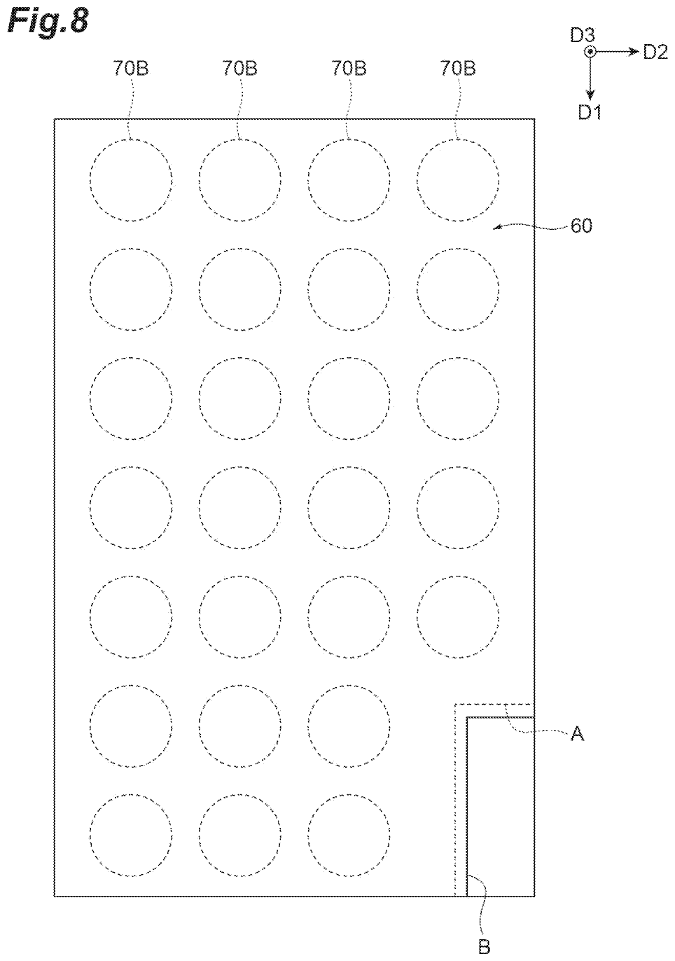

FIG. 7 is a side view illustrating a heat insulation spacer 70B, a support portion 14, and a relay board 60 of an optical transmission module according to Modified Example 2. FIG. 8 is a plan view illustrating the relay board 60 and the heat insulation spacer 70B. As illustrated in FIGS. 7 and 8, the optical transmission module according to Modified Example 2 includes a plurality of heat insulation spacers 70B. For example, each heat insulation spacer 70B has a columnar shape. The shape of each heat insulation spacer 70B may be cylindrical or prismatic (rectangular parallelepiped). When viewed from the third direction D3, the plurality of heat insulation spacers 70B are disposed in a dispersed manner. As an example, when viewed from the third direction D3, the plurality of heat insulation spacers 70B are disposed in a lattice pattern. In FIG. 8, the individual heat insulation spacers 70B are disposed to be separated from each other. It is noted that the heat insulation spacers 70B may be in contact with each other.

The heat insulation spacer 70B is disposed at the position other than the insulated space A. For example, the heat insulation spacer 70B is made of a non-conductive resin. In Modified Example 2, the total contact area between the relay board 60 and each heat insulation spacer 70B is smaller than the area of the bottom surface 65 of the relay board 60. Therefore, by forming the wider space between the portion of the bottom surface 65 of the relay board 60 and the support portion 14, the inflow of heat from the support portion 14 to the relay board 60 can be more effectively suppressed. It is noted that, since the total contact area varies depending on the contact area of each heat insulation spacer 70B and the number of heat insulation spacers 70B, the total contact area can be made smaller by reducing at least one of the contact area and the number. By reducing the total contact area, the inflow of heat into the relay board 60 can be further reduced. For example, the total contact area may be half or less the area of the bottom surface 65 of the relay board 60.

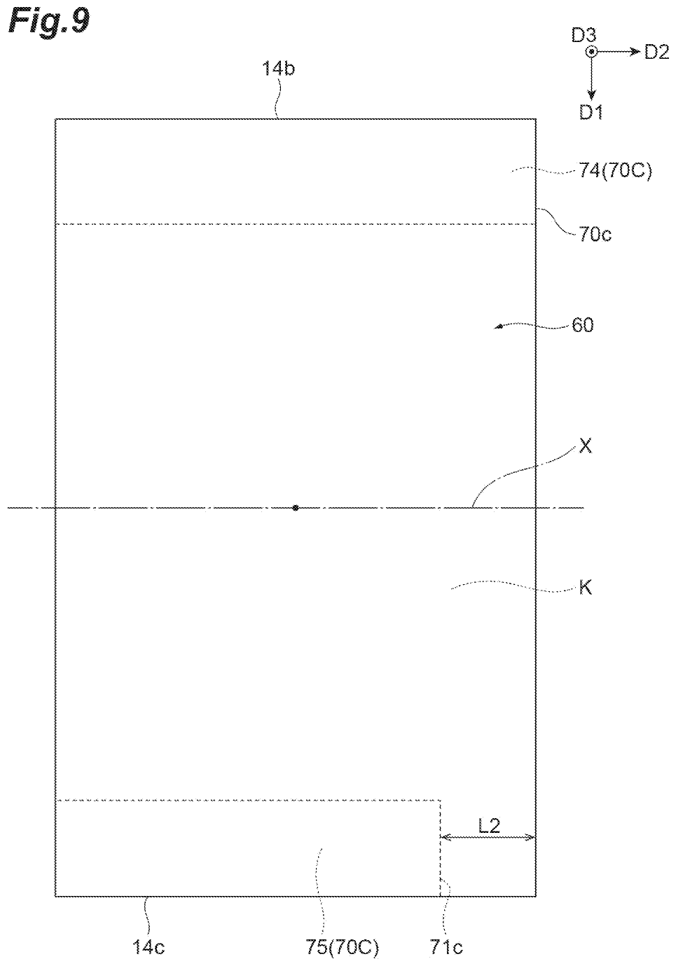

FIG. 9 is a plan view illustrating the relay board 60 and a plurality of heat insulation spacers 70C of the optical transmission module according to Modified Example 3. As illustrated in FIG. 9, an optical transmission module according to Modified Example 3 includes a plurality of heat insulation spacers 70C. The plurality of heat insulation spacers 70C include a first heat insulation spacer 74 and a second heat insulation spacer 75 disposed at the position separated from the first heat insulation spacer 74. The first heat insulation spacer 74 is disposed at the position closer to the metal stem 10 than a reference line X, which passes the center of the relay board 60 in the first direction D1 and extends along the second direction D2. The second heat insulation spacer 75 is located farther from the metal stem 10 than the reference line X. The first heat insulation spacer 74 has the end face 70c extending in the first direction D1. The second heat insulation spacer 75 has the side surface 71c. The side surface 71c is parallel to the end face 70c of the first heat insulation spacer 74, and is located further away from the dielectric block 20 than the end face 70c in the second direction D2.

For example, the first heat insulation spacer 74 is placed on a first end 14b of the support portion 14 in the first direction D1, and the second heat insulation spacer 75 is placed on a second end 14c of the support portion 14 opposite to the first end 14b. For example, the length of the first heat insulation spacer 74 in the second direction D2 is larger than the length of the second heat insulation spacer 75 in the second direction D2. As an example, the first heat insulation spacer 74 extends throughout the support portion 14 in the second direction D2. On the other hand, the second heat insulation spacer 75 extends from the end of the support portion 14 opposite to the insulated space A in the second direction D2 to the front side of the insulated space A. That is, the second heat insulation spacer 75 is disposed at the position separated from the insulated space A. For example, the second heat insulation spacer 75 is spaced apart from the end face 70c of the second heat insulation spacer 75 by a length (second distance) L2 in the second direction D2. The length L2 is set larger than the length L1 of the wire connection region B (refer to FIG. 5). An air layer K is formed between the first heat insulation spacer 74 and the second heat insulation spacer 75. In the air layer K, the relay board 60 is separated from the support portion 14. This air layer K can further reduce the inflow of heat from the support portion 14 to the relay board 60. Since the total contact area between the relay board 60 and the plurality of heat insulation spacers 70C varies depending on the contact area of the first heat insulation spacer 74 and the contact area of the second heat insulation spacer 75, the total contact area can be made smaller by reducing at least one of the contact area of the first heat insulation spacer 74 and the contact area of the second heat insulation spacer 75. By reducing the total contact area, the inflow of heat into the relay board 60 can be further reduced. For example, the total contact area may be half or less the area of the bottom surface 65 of the relay board 60.

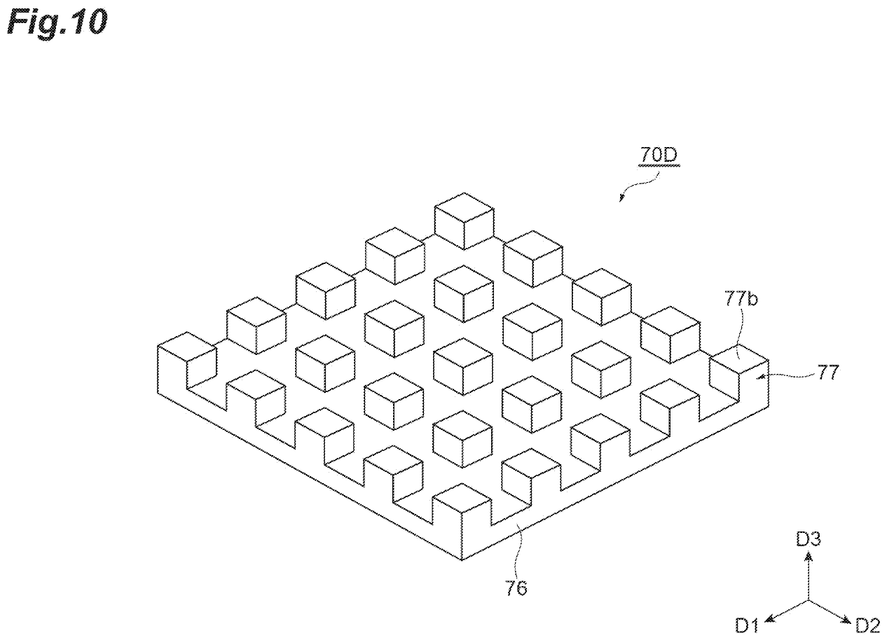

FIG. 10 is a perspective view illustrating a heat insulation spacer 70D of the optical transmission module according to Modified Example 4. The heat insulation spacer 70D includes a plate-like portion 76 mounted on the support portion 14 and a columnar portion 77 extending from the plate-like portion 76 in the third direction D3. The columnar portion 77 has an upper surface 77b that is in contact with the bottom surface 65 of the relay board 60. The heat insulation spacer 70D has the plurality of columnar portions 77. When viewed from the third direction D3, the plurality of columnar portions 77 are formed so that the individual columnar portions 77 are separated apart from each other and aligned along the first direction D1 and aligned along the second direction D2. That is, when viewed from the third direction D3, the plurality of columnar portions 77 are disposed in the lattice pattern. In this heat insulation spacer 70D, the heat insulation spacer 70D can be disposed by mounting the plate-like portion 76 on the support portion 14. In Modified Example 4, since the individual columnar portions 77 are fixed to the plate-like portion 76, the columnar portions 77 are not required to be disposed on the support portion 14 one by one. Therefore, the heat insulation spacer 70D can be disposed more easily than the heat insulation spacer 70B illustrated in FIG. 7. It is noted that, similarly to Modified Example 2, by reducing at least one of the contact area of each columnar portion 77 with the relay board 60 and the number of columnar portions 77, the inflow of heat into the relay board 60 can be further reduced. For example, the total contact area may be half or less the area of the bottom surface 65 of the relay board 60. The heat insulation spacer 70D may have the removed portion 71 similarly to the heat insulation spacer 70.

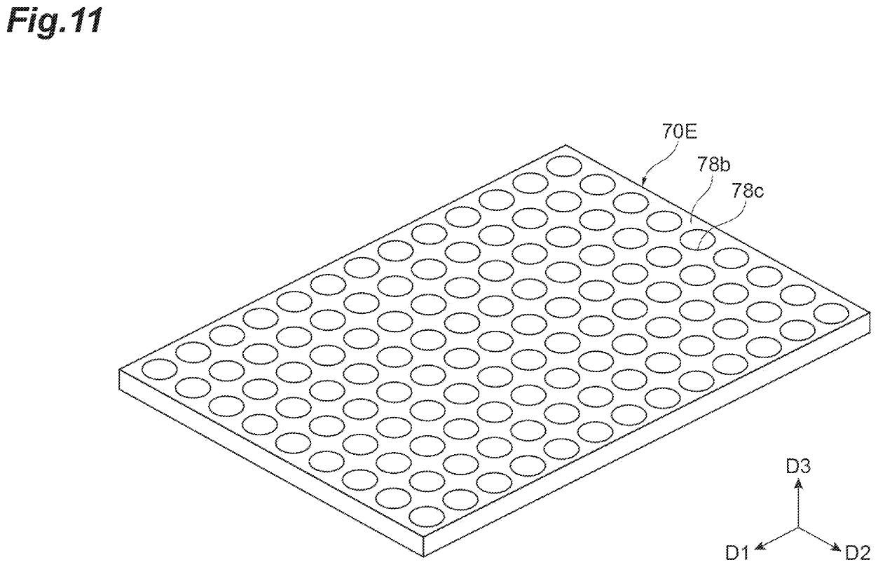

FIG. 11 is a perspective view illustrating a heat insulation spacer 70E of the optical transmission module according to Modified Example 5. The heat insulation spacer 70E has a flat plate shape that extends in both the first direction D1 and the second direction D2 and has a thickness in the third direction D3. The heat insulation spacer 70E has a surface 78b that contacts the bottom surface 65 of the relay board 60, and a penetrating hole 78c penetrating the heat insulation spacer 70E in the third direction D3. The heat insulation spacer 70E has the plurality of penetrating holes 78c. The plurality of penetrating holes 78c are arranged, for example, in the lattice pattern so that the centers are aligned at predetermined intervals. The surface 78b is, for example, the flat surface. As an example, the penetrating hole 78c has a circular shape. In this heat insulation spacer 70E, since a portion the penetrating hole 78c functions as a space between the support portion 14 and the relay board 60, the same function and effect as those of the above-described heat insulation spacer 70D or the like can be obtained. Since the penetrating hole 78c can be opened by drilling or punching, the heat insulation spacer 70E can be produced more easily than the heat insulation spacer 70D. In Modified Example 5, by increasing at least one of the area of each penetrating hole 78 and the number of penetrating holes 78, the contact area of the heat insulation spacer 70E with the relay board 60 can be reduced, and the inflow of heat into the relay board 60 can be further reduced. For example, the contact area of the surface 78b with the relay board 60 may be half or less the area of the bottom surface 65 of the relay board 60. The heat insulation spacer 70E may have the removed portion 71 similarly to the heat insulation spacer 70.

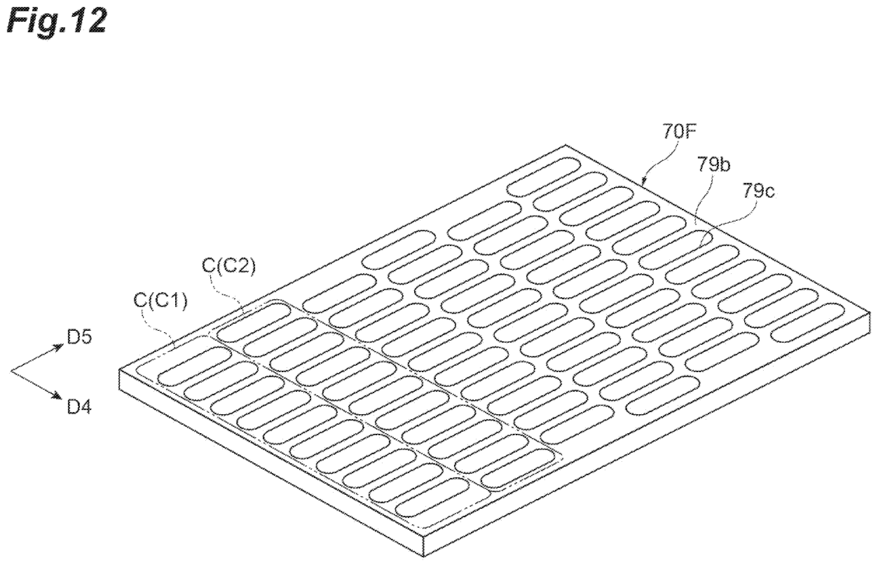

FIG. 12 is a perspective view illustrating a heat insulation spacer 70F of the optical transmission module according to Modified Example 6. The heat insulation spacer 70F has a surface 79b and a penetrating hole 79c, and differs from Modified Example 5 in that the penetrating hole 79c has a non-circular shape. For example, the penetrating hole 79c has an oval shape. The heat insulation spacer 70F has the plurality of penetrating holes 79c. Since the penetrating hole 79c can be opened by drilling or punching, the heat insulation spacer 70F can be produced relatively easily like the heat insulation spacer 70E. The contact area of the surface 79b with the relay board 60 may be half or less the area of the bottom surface 65 of the relay board 60. The heat insulation spacer 70F may have the removed portion 71 similarly to the heat insulation spacer 70.

The heat insulation spacer 70F has, for example, a plurality of groups C including the plurality of penetrating holes 79c aligned along a direction D4. The plurality of groups C are aligned along a direction D5 that intersects the direction D4. The plurality of groups C include a first group C1 and a second group C2 adjacent to the first group C1. For example, the position of the penetrating hole 79c in the first group C1 in the direction D4 is shifted from the position of the penetrating hole 79c in the second group C2 in the direction D4. As described above, the heat insulation spacer 70F having the plurality of oval-shaped penetrating holes 79c can provide the same functions and effects as the heat insulation spacer 70E and the like described above.

The embodiments and various modified examples according to the present disclosure have been described above. However, the present invention is not limited to the above-described embodiments or various modified examples, and can be modified as appropriate within the scope of the spirit described in the claims. Further, the optical transmission module according to the present disclosure may be a combination of the above-described embodiments and the plurality of examples among Modified Examples 1 to 6. For example, the configuration, shape, size, material, number, and arrangement of each portion of the optical transmission module according to the present disclosure are not limited to the embodiments or modified examples described above, and can be changed as appropriate.

What is claimed is:

1. An optical transmission module, comprising:
a metal stem having a signal terminal extending in a first direction and a support portion extending in the first direction;
a dielectric block containing a dielectric material and having a semiconductor mounting surface and a heat conduction surface;
an optical semiconductor element mounted on the semiconductor mounting surface;
a temperature control element disposed between the metal stem and the heat conduction surface;
a relay board for electrically connecting the signal terminal to the optical semiconductor element; and
a heat insulation spacer having an insulation property and connected between the support portion and the relay board,
wherein thermal conductivity of the heat insulation spacer is lower than the thermal conductivity of the support portion, and lower than the thermal conductivity of the relay board.

2. The optical transmission module according to claim 1,
wherein the thermal conductivity of the heat insulation spacer is 10 W/(m·K) or less.

3. The optical transmission module according to claim 1,
wherein the relay board has signal wiring and ground wiring, and
wherein the ground wiring is electrically connected to the metal stem at a first end of the relay board in the first direction and is electrically connected to the optical semiconductor element via a bonding wire at a second end of the relay board opposite to the first end in the first direction.

4. The optical transmission module according to claim 1,
wherein a contact area between the relay board and the heat insulation spacer is smaller than an area of a bottom surface of the relay board.
